(19) United States
(12) Patent Application Publication
(10) Pub. No.: US 2022/0318465 A1
(43) Pub. Date: Oct. 6, 2022

(54) PREDICTING AND AVOIDING FAILURES IN COMPUTER SIMULATIONS USING MACHINE LEARNING

(71) Applicant: Saudi Arabian Oil Company, Dhahran (SA)

(72) Inventors: Sulaiman M. Gannas, Dhahran (SA); Majdi A. Baddourah, Khobar (SA); Ali A. Al-Turki, Dhahran (SA); Badr M. Harbi, Dammam (SA); Osaid F. Hajjar, Dammam (SA); Babatunde Moriwawon, Khobar (SA)

(21) Appl. No.: 17/220,462

(22) Filed: Apr. 1, 2021

(51) Int. Cl. G06F 30/27; G06N 3/08; G01V 99/00

(52) U.S. Cl. CPC G06F 30/27; G06N 3/08; G01V 99/005

(57) ABSTRACT

In an example method, a system obtains first data indicating a plurality of properties of a first reservoir. The system determines, using a computerized neural network, a first metric representing a likelihood that a first computer simulation of the first reservoir can be performed to completion using a computer model and the first data. Further, the system determines that the first metric is less than a threshold level, and in response, generates a notification indicating the first metric for presentation to a user.

### TECHNICAL FIELD

The disclosure relates to systems and methods for predicting and avoiding failures in computer simulations using machine learning.

### BACKGROUND

Computer simulations can be used to model the characteristics of a physical environment. For instance, computer simulations can be used to model the flow of fluids through the porous media of a subterranean reservoir to facilitate the extraction of natural resources, such as oil or natural gas.

### SUMMARY

In some implementations, a computer system can perform one or more iterative calculation processes to simulate the characteristics of a physical environment. As an example, a computer system can retrieve input data regarding known properties of the reservoir. Further, the computer simulation can iteratively perform calculations based on the input data to simulate the flow of fluid in the reservoir. In each iteration, the parameters of the computer simulation can be modified, and the calculations can be repeated until the output of the calculations falls within an acceptable tolerance range. This may be referred to as the computer simulation “converging” onto a solution.

However, in some cases, the computer simulation may be unable to converge onto a solution, due to the particular characteristics of the input data and/or due to limitations of the computer simulation itself. In some implementation, this may cause a computer simulation to be terminated prior to completion, resulting in an unnecessary expenditure of computing resources.

Machine learning techniques can be used to preemptively identify characteristics of input data that are likely to cause a convergence failure, such that the input data can be modified or corrected prior to initiating the computer simulation. For example, a computer system can obtain multiple sets of training data, each set including (i) input data for a respective previously performed computer simulation, and (ii) an outcome of that computer simulation (for example, whether the computer simulation was successfully run to completion or was prematurely terminated due to a convergence failure). Based on the training data, the computer system can be trained to recognize characteristics of input data that are likely to result in a convergence failure and preemptively warn a user prior to the running the computer simulation.

The implementations described in this disclosure can provide various technical benefits. For instance, the machine learning processes described herein enable a computer system to reduce the frequency by which computer simulations are prematurely terminated mid-run due to convergence failures. Accordingly, the computer system can perform computer simulations in a more efficient manner (for example, by eliminating or otherwise reducing an unnecessary expenditure of computing resources).

In an aspect, a method includes obtaining, using one or more processors, first data indicating a plurality of properties of a first reservoir; determining, using the one or more processors implementing a computerized neural network, a first metric representing a likelihood that a first computer simulation of the first reservoir can be performed to completion using a computer model and the first data; determining, using the one or more processors, that the first metric is less than a threshold level; and responsive to determining that the first metric is less than the threshold level, generating, using the one or more processors, a notification indicating the first metric for presentation to a user.

Implementations of this aspect can include one or more of the following features.

In some implementations, the first metric can be determined prior to a performance of the first computer simulation of the first reservoir by a computer system.

In some implementations, the computer system can be a distributed computer system.

In some implementations, the method can further include, responsive to determining that the first metric is less than the threshold level, preventing the computer system from performing the first computer simulation using the computer model and the first data.

In some implementations, the method can further include identifying one or more portions of the first data that are likely to prevent the first computer simulation of the first reservoir from being performed to completion using the computer model. The notification can indicate the one or more identified portions of the first data.

In some implementations, the method can further include determining one or more modifications to the one or more portions of the first data that would enable the first computer simulation of the first reservoir to be performed to completion using the computer model. The notification can indicates the one or more modifications.

In some implementations, the method can also include modifying the first data according to the one or more determined modifications.

In some implementations, the computerized neural network can be trained based a plurality of sets of training data regarding a plurality of additional reservoirs. Each of the sets of training data can include an indication of a plurality of properties of a respective one of the additional reservoirs, and an indication whether an additional computer simulation of that additional reservoirs was previously performed to completion using the computer model.

In some implementations, the properties of the first reservoir can include a characteristic of rock at a particular location of the reservoir, a physical geometry of the reservoir at the particular location, a permeability of the reservoir at the particular location, or a characteristics of fluid at the particular location of the reservoir.

In some implementations, the first data can further indicate one or more characteristics of an industrial process performed at the reservoir.

In some implementations, the industrial process can be a well production process and/or a fluid injection process.

In some implementations, the first data can further indicate one or more tolerances of the computer simulation.

In some implementations, the first computer simulation can simulate a time dependent flow of fluid through the reservoir.

In some implementations, determining the first metric can include determining a spatial grid for performing the computer simulation of the reservoir. The spatial grid can include a plurality of grid blocks. Each of the grid blocks can corresponds to a different respective spatial region of the reservoir. Further, determining the first metric can include determining, for each of the grid blocks, a second metric for that grid block. Each of the second metrics can represent a likelihood that the properties of the first reservoir at a corresponding one of the spatial regions would cause the first computer simulation to terminate prior to completion due to one or more failure conditions.

In some implementations, the one or more failure conditions can include a convergence failure in performing an iterative process of the first computer simulation.

Other implementations are directed to systems, devices, and devices for performing some or all of the method. Other implementations are directed to one or more non-transitory computer-readable media including one or more sequences of instructions which when executed by one or more processors causes the performance of some or all of the method.

The details of one or more embodiments are set forth in the accompanying drawings and the description. Other features and advantages will be apparent from the description and drawings, and from the claims.

### BRIEF DESCRIPTION OF DRAWINGS

FIG. 1 is a diagram of an example system for performing computer simulations to simulate the characteristics of a subterranean reservoir.

FIG. 2 is a diagram of an example failure prediction system.

FIG. 3 is a diagram of an example neural network.

FIG. 4 is a flow chart diagram of an example process for training a neural network.

FIG. 5 is a diagram of an example graphical user interface for presenting metrics to a user.

FIG. 6 is a flow chart diagrams of example processes for predicting and avoiding failures in computer simulations using machine learning.

FIG. 7 is a schematic diagram of an example computer system.

### DETAILED DESCRIPTION

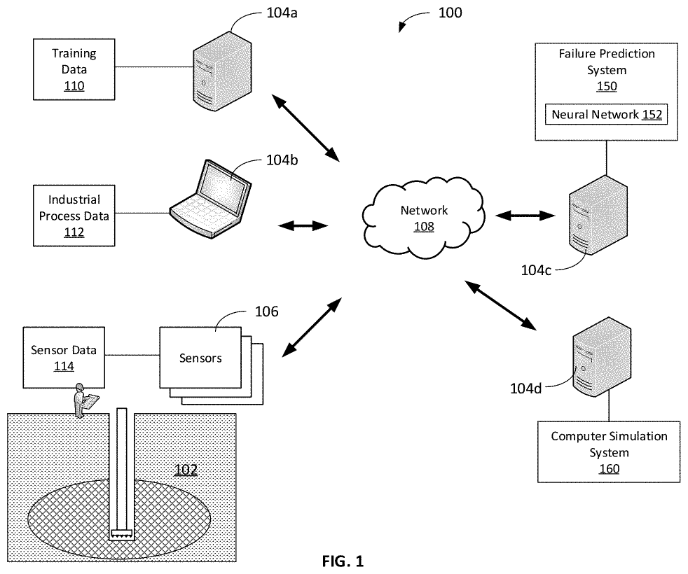

FIG. 1 shows an example system 100 for performing computer simulations to simulate the characteristics of a subterranean reservoir 102. The system 100 includes several computer systems 104a-102d and sensors 106 communicatively coupled to one another through a network 108. Further, a failure prediction system 150 including a neural network 152 is maintained on at least one of the computer systems (for example, the computer system 104c), and a computer simulation system 160 is maintained on at least one of the computer systems (for example, the computer system 104d).

During an example operation of the system 100, the system 100 obtains data to be used in a computer simulation. As an example, to simulate the characteristics of the subterranean reservoir 102 (often referred to as performing a “reservoir simulation”), the system 100 can obtain industrial process data 112 regarding one or more industrial processes that are being performed or are anticipated to be performed with respect to the reservoir 102. Further, the system 100 can obtain sensor data 114 (for example, from one or more sensors 104) regarding the properties of the reservoir 102.

Based on the input data, the system 100 can perform one or more iterative calculation processes to simulate the characteristics of the reservoir 102. As an example, the input data can be provided to the computer simulation system 160 for processing. The computer simulation system 160 can iteratively perform calculations based on the input data to simulate the flow of fluid in the reservoir 102. In each iteration, the parameters of the computer simulation can be modified, and the calculations can be repeated until the output of the calculations falls within an acceptable tolerance range (for example, such that the computer simulation converges onto a solution).

However, in some cases, the computer simulation may be unable to converge onto a solution, due to the particular characteristics of the input data and/or due to limitations of the computer simulation itself. In some implementation, this may cause a computer simulation to be terminated prior to completion, resulting in an unnecessary expenditure of computing resources.

In some implementations, a computer simulation can be performed according to a sequence of time steps (for example, to simulate the characteristics of the reservoir 102 over time). In some implementations, a computer simulation can be initially performed according to a particular time step value. If the computer simulation is unable to converge to a solution according to that time step value, the computer simulation can modify the time step value (for example, reduce the time step value), and attempt to converge to a solution according to the modified time step value. In some implementations, a computer system can attempt to perform a computer simulation at successively smaller time steps values until a particular threshold value is reached. If the computer simulation does not converge when the threshold value is reached, the computer system can terminate the computer simulation and indicate that a convergence failure has occurred.

Machine learning techniques can be used to preemptively identify characteristics of input data that are likely to cause a convergence failure, such that the input data can be modified or corrected prior to initiating the computer simulation. For example, the failure prediction system 150 can obtain multiple sets of training data 110, each set including (i) input data for a respective previously performed computer simulation, and (ii) an outcome of that computer simulation (for example, whether the computer simulation was successfully run to completion or was prematurely terminated due to a convergence failure). Based on the training data 110, the failure prediction system 150 can train a neural network 152 to recognize characteristics of input data that are likely to result in a convergence failure.

In some implementations, the neural network 152 can receive input data, and output a metric based on the input data. The metric can indicate the likelihood that the input data would result in a convergence failure if the input data were to be used to perform a computer simulation. As an example a metric having a higher value can indicate that the input data is more likely to result in a convergence failure, whereas a metric having a lower value can indicate that the input data is less likely to result in a convergence failure.

In some implementations, the failure prediction system 150 can preemptively warn a user regarding the likelihood that the input data would result in a convergence error, prior to the initiation of the computer simulation. For instance, if the metric exceeds a particular threshold value (for example, indicating that the likelihood that the input data would result in a convergence failure is sufficiently high), the failure prediction system 150 can generate a notification to a user to warn the user. Further, the failure prediction system 150 can identify specific aspects of the input data that may cause or otherwise contribute to the convergence failure, and notify the user of those aspects. This technique can be beneficial, for example, in assisting the user to modify or correct the input data, such that a convergence failure is less likely to occur once the computer simulation is actually performed.

Further, in some implementations, the failure prediction system 150 can preemptively prevent a computer simulation from being performed using the input data, until the input data has been modified or correctly to reduce the likelihood of a convergence failure. For instance, if the metric exceeds a particular threshold value (for example, indicating that the likelihood that the input data would result in a convergence failure is sufficiently high), the failure prediction system 150 can prevent the computer simulation system 160 from initiating a computer simulation using that input data. This technique can be beneficial, for example, in reducing the frequency by which computer simulations are prematurely terminated mid-run due to convergence failures. Accordingly, the system 100 can perform computer simulations in a more efficient manner (for example, by eliminating or otherwise reducing an unnecessary expenditure of computing resources).

Each of the computer systems 104a-104d can include any number of electronic device that are configured to receive, process, and transmit data. Examples of the computer systems 104a-104d include client computing devices (such as desktop computers or notebook computers), server computing devices (such as server computers or cloud computing systems), mobile computing devices (such as cellular phones, smartphones, tablets, personal data assistants, notebook computers with networking capability), wearable computing devices (such as a smart phone or a headset), and other computing devices capable of receiving, processing, and transmitting data. In some implementations, the computer systems 104a-104d can include computing devices that operate using one or more operating systems (as examples, Microsoft Windows, Apple macOS, Linux, Unix, Google Android, and Apple iOS, among others) and one or more architectures (as examples, x86, PowerPC, and ARM, among others). In some implementations, one or more of the computer system 104a-104d need not be located locally with respect to the rest of the system 100, and one or more of the computer systems 104a-104d can be located in one or more remote physical locations.

Each the computer systems 104a-104d can include a respective user interface that enables users interact with the computer system 104a-104d, the failure prediction system 150, and the computer simulation system 160, such as to view data from one or more of the computer systems 104a-104d, the failure prediction system 150, or the computer simulation system 160, transmit data from one computer system to another, or to issue commands to one or more of the computer systems 104a-104d, the failure prediction system 150, or the computer simulation system 160. Commands can include, for example, any user instruction to one or more of the computer system 104a-104d, the failure prediction system 150, or the computer simulation system 160 to perform particular operations or tasks. In some implementations, a user can install a software application onto one or more of the computer systems 104a-104d to facilitate performance of these tasks.

In FIG. 1, the computer systems 104a-104d are illustrated as respective single components. However, in practice, the computer systems 104a-104d can be implemented on one or more computing devices (for example, each computing device including at least one processor such as a microprocessor or microcontroller). As an example, the computer system 104c can be a single computing device that is connected to the network 108, and the failure prediction system 150 can be maintained and operated on the single computing device. As another example, the computer system 104c can include multiple computing devices that are connected to the network 108, and the failure prediction system 150 can be maintained and operated on some or all of the computing devices. For instance, the computer system 104c can include several computing devices, and the failure prediction system 150 can be distributive on one or more of these computing devices.

The network 108 can be any communications network through which data can be transferred and shared. For example, the network 108 can be a local area network (LAN) or a wide-area network (WAN), such as the Internet. The network 108 can be implemented using various networking interfaces, for instance wireless networking interfaces (such as Wi-Fi, Bluetooth, or infrared) or wired networking interfaces (such as Ethernet or serial connection). The network 108 also can include combinations of more than one network, and can be implemented using one or more networking interfaces.

As described above, input data for a computer simulation can include industrial process data 112 regarding one or more industrial processes. As an example, an industrial process can include drilling a wellbore to access the reservoir 102, constructing a well using the wellbore, and producing natural resources (for example, oil or natural gas) from the reservoir 102 using the well. The industrial process data 112 can include characteristics of this process. As an example, the industrial process data 112 can include the rate at which natural resources are produced (or are anticipated to be produced) using the well. As another example, the industrial process data 112 can include the rate at which fluids are injected (or are anticipated to be injected) into the reservoir 102, such as to maintain a particular pressure in the reservoir 102 and/or to drive natural resources in the reservoir 102 towards the well during the production process. In some implementations, the industrial process data 112 can be provided by the computer system 104b (for example, based on user input).

As described above, input data for a computer simulation can include sensor data 114 obtained by one or more sensors 106 regarding the properties of the reservoir 102. For instance, the sensors 106 can be positioned in or around the reservoir 102, and can be configured to measure one or more properties of the reservoir 102. Example sensors 106 include temperature sensors, groundwater sensors, vapor sensors, optical sensors, vibrating or tuning fork sensors, ultrasonic sensors, float sensors, capacitance sensors, radar sensors, conductivity or resistance sensors, and any other sensors for measuring properties in and around the reservoir 102.

In some implementations, the sensor data 114 can include measurements regarding the permeability and porosity of rock at each of several locations in the reservoir 102. For example, the reservoir 102 can be notionally divided into a grid. For each grid block in the grid, the sensor data 114 can include measurements regarding the permeability and porosity of rock at that particular grid block. In some implementations, the sensor data 114 can also include statistical information regarding the measurements, such as the minimum measured value, maximum measured value, average measured value, and/or standard deviation of the measure values in each particular grid block and/or in the entirety of the grid.

In some implementations, the sensor data 114 can include measurements regarding the relative permeability of rock at each of several locations in the reservoir 102. The relative permeability of a phase is a dimensionless measure of the effective permeability of that phase. In particular, the relative permeability is the ratio of the effective permeability of that phase to the absolute permeability.

In some implementations, the sensor data 114 can include measurements regarding the pressure, volume, and/or temperature at each of several locations in the reservoir 102. For example, for each grid block in a notional grid, the sensor data 114 can include measurements regarding the pressure, volume, and/or temperature of fluid at that particular grid block. In some implementations, the sensor data 114 can also include statistical information regarding the measurements, such as the minimum measured value, maximum measured value, average measured value, and/or standard deviation of the measure values in each particular grid block and/or in the entirety of the grid.

In some implementations, the sensor data 114 can include measurements regarding a physical geometry of the reservoir 102 and/or the sub-structures of the reservoir 102. For example, the sensor data 114 can include measurements regarding the dimensions and depth the reservoir 102. As another example, the sensor data 114 can include measurements regarding the dimensions and location of each of the sub-structures of the reservoir 102, such as the depth of each of the sub-structures and the geographical coordinates of each of the sub-structures.

In some implementations, the input data can also include information regarding the computer simulation that will be performed using the computer simulation system 160. As an example, the input data can include one or more tolerances for a numerical solver used to perform the computer simulation.

As described above, the failure prediction system 150 can use training data 110 to train the neural network 152 to recognize characteristics of input data that are likely to result in a convergence failure. As an example, the failure prediction system 150 can obtain multiple sets of training data 110, each set including (i) input data for a respective previously performed computer simulation, and (ii) an outcome of that computer simulation (for example, whether the computer simulation was successfully run to completion or was prematurely terminated due to a convergence failure). Further, the failure prediction system 150 can train the neural network 152 to recognize particular trends, patterns, or correlations between the characteristics of input data, and the outcome of a computer simulation that was performed using that input data. Example training data and training techniques are described in further detail below.

The input data in each set of training data 110 can be similar to the input data described above. For instance, for each set of training data 110, the input data can include industrial process data regarding one or more industrial processes performed (or anticipated to be performed at a respective reservoir, sensor data obtained by one or more sensors regarding the properties of that reservoir, and information regarding a computer simulation that was performed based on the input data.

Further, each set of training data 110 can include an outcome of a computer simulation that was performed using the input data in that set. For example, if a computer simulation was performed to completion using the input data, the set of training data 110 can indicate that the computer simulation was successfully performed. As another example, if a computer simulation was not performed to completion, the set of training data 110 can indicate the reason that the computer simulation was prematurely terminated (for example, due to a convergence failure), and the portion of the computer simulation that was completed prior to the termination of the computer simulation.

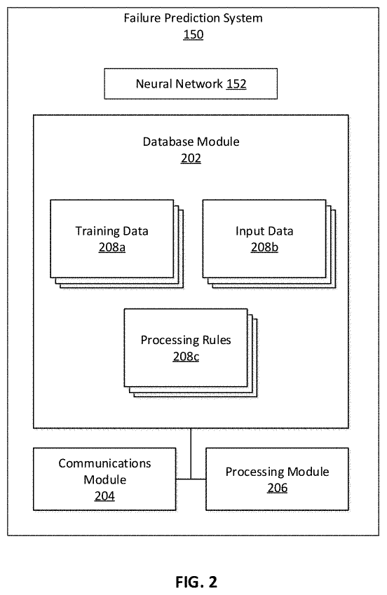

FIG. 2 shows various aspects of the failure prediction system 150. The failure prediction system 150 includes a neural network 152 and several modules that perform particular functions related to the operation of the system 100. For example, the failure prediction system 150 can include a database module 202, a communications module 204, and a processing module 206.

The database module 202 maintains information related to predicting convergence failures in computer simulations using the neural network 152. As an example, the database module 202 can store training data 208a that is used to train the neural network 152 to predict convergence failures in computer simulations. The training data 208a can include historical information regarding one or more computer simulations that were previously performed, the input data that was used to perform the computer simulations, and the outcome of those computer simulations. In some implementations, the training data 208a can be similar to the training data 110 described with respect to FIG. 1.

Further, the database module 202 can store input data 208b to be used to a computer simulation. As an example, the input data 208b can include the industrial process data 112, the sensor data 114, and/or additional data regarding the computer simulation, as described with respect to FIG. 1.

Further, the database module 202 can store processing rules 208c specifying how data in the database module 202 can be processed to train a neural network 152 to predict convergence failures in computer simulations. For instance, the processing rules 208c can specify how the training data 208a is used by the failure prediction system 150 to train a neural network 152 to predict convergence failures in computer simulations based on the characteristics of input data.

For example, the processing rules 208c can specify one more machine learning or artificial intelligence processes for identifying patterns, trends, or correlations in the input data that indicate that a convergence failure is likely to occur if the input data were to be used to perform a computer simulation. As another example, the processing rules 208c can specify that at least a portion of the training data 208a be used as input data in the machine learning or artificial intelligence processes (for example, to provide “ground truth” examples that can aid in the identification of patterns or trends). Accordingly, the failure prediction system 150 can be trained to predict the occurrence of convergence failures for new computer simulations based on information regarding previously performed computer simulations. In some implementations, the processing rules 208c can specify that the neural network 152 be iteratively trained and re-trained with successive sets of training data 208a (for example, additional sets of training data 208a that are collected over time) to progressively improve its accuracy in predicting convergence failures. In some implementations, the processing rules 208c can specify that a training process be performed automatically by the failure prediction system 150 without manual user input.

As another example, the processing rules 208c can specify that the neural network 152 receives the input data 208b, and outputs a metric based on the input data 208b. As described above, the metric can indicate the likelihood that the input data 208b would result in a convergence failure if the input data 208b were to be used to perform a computer simulation. Further, the processing rules 208c can specify that the neural network 152 identify specific aspects of the input data 208b that may cause or otherwise contribute to a convergence failure.

Example machine learning or artificial intelligence process are described in further detail below.

In some implementation, the processing rules 208c can specify that the failure prediction system 150 preemptively warns a user regarding the likelihood that the input data 208b would result in a convergence error, prior to the initiation of the computer simulation. For instance, the processing rules 208c can specify that if the metric exceeds a first threshold value (for example, indicating that the likelihood that the input data would result in a convergence failure is sufficiently high), the failure prediction system 150 is to generate a notification to a user to warn the user. Further, the failure prediction system 150 can identify specific aspects of the input data that may cause or otherwise contribute to the convergence failure, and notify the user of those aspects.

Further, in some implementations, the processing rules 208c can specify that the failure prediction system 150 preemptively prevents a computer simulation from being performed using the input data 208b, until the input data 208b has been modified or corrected to reduce the likelihood of a convergence failure. For instance, the processing rules 208c can specify that if the metric exceeds a second threshold value (for example, indicating that the likelihood that the input data would result in a convergence failure is sufficiently high), the failure prediction system 150 is to prevent the computer simulation system 160 from initiating a computer simulation using that input data 208b.

As described above, the failure prediction system 150 also includes a communications module 204. The communications module 204 allows for the transmission of data to and from the failure prediction system 150. For example, the communications module 204 can be communicatively connected to the network 108, such that it can transmit data to and receive data from each of the computer systems 104a-104d and the sensors 106. Information received from the computer systems 104a-104d and sensors 106 can be processed (for example, using the processing module 206) and stored (for example, using the database module 202).

As described above, the failure prediction system 150 also includes a processing module 206. The processing module 206 processes data stored or otherwise accessible to the failure prediction system 150. For instance, the processing module 206 can generate the neural network 152 to predict convergence failures in computer simulations, given particular training data 208a and processing rules 208c. Further, the processing module 206 can determine a likelihood that a convergence failure will occur in a computer simulation, based on the neural network 152 and given particular input data 208b.

Further, the processing module 206 can modify the neural network 152 based the training data 208a and the processing rules 208c. For example, as described above, the processing module 206 can perform one or more machine learning or artificial intelligence processes to identify patterns, trends, or correlations in input data that indicate that a convergence failure is likely to occur if the input data were to be used to perform a computer simulation. The identified patterns, trends, or correlations can be used to generate or modify one or more of the processing rules 208c for generating and updating the neural network 152 (for example, to distinguish between different sets of input data and outcomes). Further, as described above, at least a portion of the training data 208a can be used as input data in the machine learning or artificial intelligence processes. Further, as described above, the processing module 206 can perform the training processes iteratively using successive sets of training data 208a to progressively improve the neural network's accuracy in predicting convergence failures in computer simulations. In some implementations, this training process can be performed automatically by the processing module 206 without manual user input.

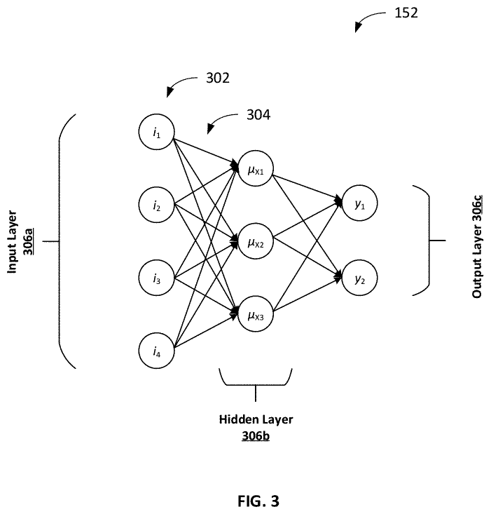

As described above, a machine learning or particular intelligence process can be performed using one or more neural networks 152. A simplified example of a neural network 152 is shown in FIG. 3.

The neural network 152 includes several nodes 302 (often called “neurons”) interconnected with another by interconnections 304. Further, the nodes 302 are arranged according to multiple layers, including an input layer 306a, a hidden layer 306b, and an output layer 306c. The arrangement of the nodes 302 and the interconnections 304 between them represent a mathematical transformation of input data (for example, as received by the nodes of the input layer 306a) into corresponding output data (for example, as output by the nodes of the output layer 306c). In some implementations, the input data can represent one or more data points obtained by the failure prediction system 150, and the output data can represent one or more corresponding outcomes or metrics generated by the failure prediction system 150 based on the input data.

The nodes 302 of the input layer 306a receive input values and output the received input values to respective nodes of the next layer of the neural network 152. In this example, the neural network 152 includes several inputs iᵢ, i₂, i₃, and i₄, each of which receives a respective input value and outputs the received value to one or more of the nodes μₓ₁, μₓ₂, and μₓ₃ (for example, as indicated by the interconnections 304).

In some implementations, at least some of the information stored by the database module (for example, the input data 208b) can be used as inputs for the nodes of the input layer 306a. For example, at least some of the information stored by the database module can be expressed numerically (for example, assigned a numerical score or value), and input into the nodes of the input layer 306a.

The nodes of the hidden layer 306b receive input values (for example, from the nodes of the input layer 306a or nodes of other hidden layers), applies particular transformations to the received values, and outputs the transformed values to respective nodes of the next layer of the neural network 152 (for example, as indicated by the interconnections 304). In this example, the neural network 152 includes several nodes μₓ₁, μₓ₂, and μₓ₃, each of which receives respective input values from the nodes i₁, i₂, i₃, and i₄, applies a respective transformation to the received values, and outputs the transformed values to one or more of the nodes y₁ and y₂.

In some implementations, nodes of the hidden layer 306b can receive one or more input values, and transform the one or more received values according to a mathematical transfer function. As an example, the values that are received by a node can be used as input values in particular transfer function, and the value that is output by the transfer function can be used as the output of the node. In some implementations, a transfer function can be a non-linear function. In some implementations, a transfer function can be a linear function.

In some implementations, a transfer function can weight certain inputs differently than others, such that certain inputs have a greater influence on the output of the node than others. For example, in some implementations, a transfer function can weight each of the inputs by multiplying each of the inputs by a respective coefficient. Further, in some implementations, a transfer function can apply a bias to its output. For example, in some implementations, a transfer function can bias its output by a particular offset value.

For instance, a transfer function of a particular node can be represented as:

$$Y = {\sum }_{i = 1}^{n} ( {weight}_{i} * {input}_{i} ) + bias ,$$

where weightᵢ is the weight that is applied to an input inputᵢ, bias is a bias or offset value is that is applied to the sum of the weighted inputs, and Y is the output of the node.

The nodes of the output layer 306c receive input values (for example from the nodes of the hidden layer 306b) and output the received values. In some implementations, nodes of the output layer 306c can also receive one or more input values, and transform the one or more received values according to a mathematical transfer function (for example, in a similar manner as the nodes of the hidden layer 306b). As an example, the values that are received by a node can be used as input values in particular transfer function, and the value that is output by the transfer function can be used as the output of the node. In some implementations, a transfer function can be a non-linear function. In some implementations, a transfer function can be a linear function.

In some implementations, at least one of the nodes of the output layer 306c can correspond to a metric that indicates the likelihood that a particular set of input data would result in a convergence failure if that input data were to be used to perform a computer simulation. As an example a metric having a higher value can indicate that the input data is more likely to result in a convergence failure, whereas a metric having a lower value can indicate that the input data is less likely to result in a convergence failure.

In this example, the neural network 152 includes two output nodes y₁ and y₂, each of which receives respective input values from the nodes μₓ₁, μₓ₂, and μₓ₃, applies a respective transformation to the received values, and outputs the transformed values as outputs of the neural network 152.

Although FIG. 3 shows example nodes and example interconnections between them, this is merely an illustrative example. In practice, a neural network can include any number of nodes that are interconnected according to any arrangement. Further, although FIG. 3 shows a neural network 152 having a single hidden layer 306b, in practice, a network can include any number of hidden layers (for example, one, two, three, four, or more), or none at all.

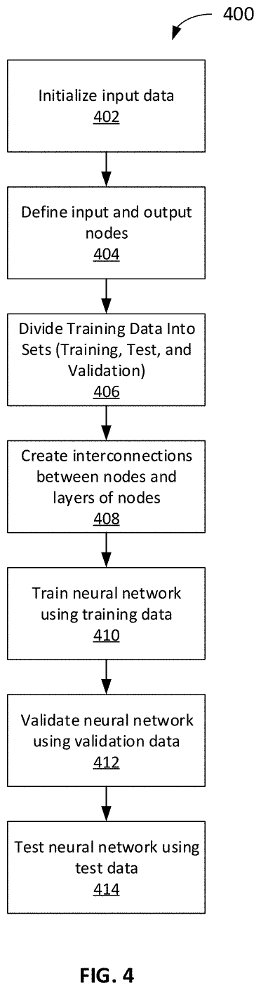

In some implementations, the neural network 152 can be trained based on training data, such as the training data 208a stored in the database module 202. An example process 400 for training the neural network 152 is shown in FIG. 4.

According to the process 400, the failure prediction system 150 initializes the input data that is used to train the neural network 152 (block 402). As an example, the failure prediction system 150 can retrieve at least a portion of the training data 208a, as described above.

Further, the failure prediction system 150 defines the input and the output nodes of the neural network 152 (block 404). For example, the failure prediction system 150 can select one or more of the types of data include in the training data 208a (for example, as described above), and specify that they be used as respective input nodes in the neural network 152 (for example, as inputs for respective nodes of the input layer 306a). As another example, the failure prediction system 150 can specify each of the outputs of the neural network (for example, the outputs of each of the nodes of the output layer 306c). For instance, at least one of the nodes of the output layer 306c can correspond to the likelihood that a particular set of input data would result in a convergence failure if that input data were to be used to perform a computer simulation.

The failure prediction system 150 divides the training data 208a into different sets (block 406). For example, the training data 208a can be divided into a training set, a validation set, and a test set.

The training set can be used to train the neural network 152. For example, the training set can be used to identify patterns, trends, or correlations between the inputs and the outputs of the neural network 152, and to express those relationships using the nodes and interconnections between them.

The validation set can be used to tune the performance of the trained neural network 152. For example, the validation set can be used to determine a difference between the output of the neural network 152 given certain inputs, and an expected output. The configuration of the neural network can be modified based on the different (for example, such that the output of the neural network 152 better matches the expected result).

The test set can be used to evaluate the performance of the trained neural network 152 (for instance, after it has been tuned based on the validation set). For example, the test set can be used to determine a difference between the output of the neural network 152 given certain inputs, and an expected output. This difference can indicate the ability of the neural network 152 to accurately predict a particular outcome (for example, likelihood that a convergence failure would occur) given particular inputs (for example, particular input data).

Further, the failure prediction system 150 creates interconnections between the nodes and layers of nodes in of the neural network 152. In some implementations, an interconnection between two or more nodes can be in the forward direction (for example, data can be passed between nodes in the direction of the input to the output of the neural network 152). This may be referred to as a “feed forward” interconnection. In some implementations, an interconnection between two or more nodes can be in the backward direction (for example, data can be passed between nodes in the direction of the output to the input of the neural network 152). This may be referred to as a “back propagation” interconnection.

Further, the failure prediction system 150 creates layers of nodes. For example, the failure prediction system 150 can specify that the neural network include N layers of nodes, such as one input layer, one output layer, and N−2 hidden layers. Other arrangements of layers are also possible, depending on the implementation.

Further, the failure prediction system 150 trains the neural network 152 using the training set (block 410). In some implementations, the failure prediction system 150 can perform the training based on a supervised learning method. As an example, the training set can include example input data and output data. Based on the arrangement of the nodes and the interconnections between them, the failure prediction system 150 can identify transfer functions for each of the nodes that would result in the output of the neural network 152 matching or otherwise being similar to the output data in the training set, given the same input data. In some implementations, the failure prediction system 150 can select particular weights or biases for each of the transfer functions. In some implementations, this can be performed iteratively (for example, using successive sets of training data).

After training the neural network 152, the failure prediction system 150 validates the neural network 152 using the validation set (block 412). As an example, the validation set can include example input data and output data. The failure prediction system 150 can input the input data into the neural network 152, and compare the output of the neural network 152 to the output data of the validation set. In some implementations, the failure prediction system 150 can calculate an “error” of the neural network 152, such as the difference between the output data of the validation set and the output of the neural network 152.

In some implementations, the failure prediction system 150 can tune the neural network 152 based on the validation set. For example, the failure prediction system 150 can modify the arrangement of the nodes, the interconnections between them, and/or the transfer functions (for example, the weights and biases) such that the error of the neural network 152 is reduced.

In some implementations, this can be performed iteratively (for example, using successive sets of validation data) until particular criteria are met. For example, in some implementations, the failure prediction system 150 can iteratively tune the neural network 152 until the error of the neural network 152 is less than a particular threshold value. As another example, the failure prediction system 150 can iteratively tune the neural network 152 until the neural network 152 exhibits a sufficiently low false positive rate (for example, the rate in which it determines that a convergence failure will occur, when in fact a convergence failure would not occur) and/or a sufficiently low false negative rate (for example, the rate in which it determines that a convergence failure will not occur, when in fact a convergence failure would occur).

After training and tuning the neural network 152, the failure prediction system 150 tests the neural network 152 using the test set (block 414). As an example, the test set can include example input data and output data. The failure prediction system 150 can input the input data into the neural network 152, and compare the output of the neural network 152 to the output data of the test set. In some implementations, the failure prediction system 150 can calculate an “error” of the neural network 152, such as the difference between the output data of the test set and the output of the neural network 152. This error can represent the predictive performance of the neural network 152. For example, a high error can indicate that the neural network 152 is less likely to predict an outcome accurately, given certain input data. Conversely, lower error can indicate that the neural network 152 is more likely to predict an outcome accurately, given certain input data.

As described above, in some implementations, the failure prediction system 150 can use the neural network 152 to identify specific aspects of input data that may cause or otherwise contribute to the convergence failure, and notify the user of those aspects. As an example, a first portion of the input data may cause or otherwise contribute greatly to a convergence failure, whereas a second portion of the input data may have comparatively smaller contribution (or no contribution at all) to a convergence failure. The failure prediction system 150 can identify the first portion of the input data to the user, such that the user can modify or correct the first portion of the input data.

As an example, a portion of the input data may be incomplete. For instance, data may be incomplete due to a malfunction in the sensors 106 and/or data corruption in the storing and processing of the input data. In some implementations, input data may be missing portions of data for particular data acquisition time points and/or missing portions of data regarding particular locations in the reservoir 102. This missing data may cause or otherwise contribute to a convergence failure. The failure prediction system 150 can identify the missing data, and suggest a modification to the input data to correct the missing data. In some implementations, the failure prediction system 150 can automatically perform the suggested modifications.

As another example, a portion of the input data may include outlier data and/or noise. For instance, data may include outlier data and/or noise due to a malfunction in the sensors 106 and/or data corruption in the storing and processing of the input data. In some implementations, input data may include outlier data or noise for particular data acquisition time points and/or for particular locations in the reservoir 102. These outliers or noise also may cause or otherwise contribute to a convergence failure. The failure prediction system 150 can identify the outlier data and/or noise, and suggest a modification to the input data to correct the outlier data and/or noise. In some implementations, the failure prediction system 150 can automatically perform the suggested modifications.

As another example, a portion of the input data may be inconsistent with other portions of the input data. For instance, data may include inconsistences due to data entry errors by users. As another example, data may include inconsistences due to an inadvertent duplication of data by a user to computer system. In some implementations, input data may include inconsistencies for particular data acquisition time points and/or for particular locations in the reservoir 102. These inconsistencies also may cause or otherwise contribute to a convergence failure. The failure prediction system 150 can identify the inconsistent data, and suggest a modification to the input data to correct the inconsistent data. In some implementations, the failure prediction system 150 can automatically perform the suggested modifications.

In some implementations, the failure prediction system 150 can use the neural network 152 to identify the specific portions of the input data that may cause or otherwise contribute to the convergence failure. For example, as described above, the reservoir 102 can be notionally divided into a grid. Further, the input data can include information specific to each of the grid blocks of the grid. The failure prediction system 150 can use the neural network 152 to identify particular grid blocks that are associated with missing data, outlier data, noise, and/or inconsistent data, and identify those grid blocks to a user.

Further, in some implementations, the failure prediction system 150 can use the neural network 152 to identify a relative contribution of each of the grid blocks to a convergence failure. For instance, the failure prediction system 150 can determine a metric for each of the grid blocks of the grid. The metric can indicate a relative contribution of that grid block (and the input data associated with that grid block) to a convergence failure. For example, if a particular grid block is associated with input data that has a larger contribution to a convergence failure, the metric for that grid block can be assigned to higher value. As another example, if a particular grid block is associated with input data that has a smaller contribution to a convergence failure, the metric for that grid block can be assigned to smaller value.

In some implementations, the metric can be categorized into different discrete levels of severity. For example, if the metric for a grid block is less than a first threshold value, the metric for that grid block can be categorized as a “very low” severity level. As another example, if the metric for a grid block is greater than or equal to the first threshold value and less than a second threshold value, the metric for that grid block can be categorized as a “low” severity level. As another example, if the metric for a grid block is greater than or equal to the second threshold value and less than a third threshold value, the metric for that grid block can be categorized as a “medium” severity level. As another example, if the metric for a grid block is greater than or equal to the third threshold value, the metric for that grid block can be categorized as a “high” severity level.

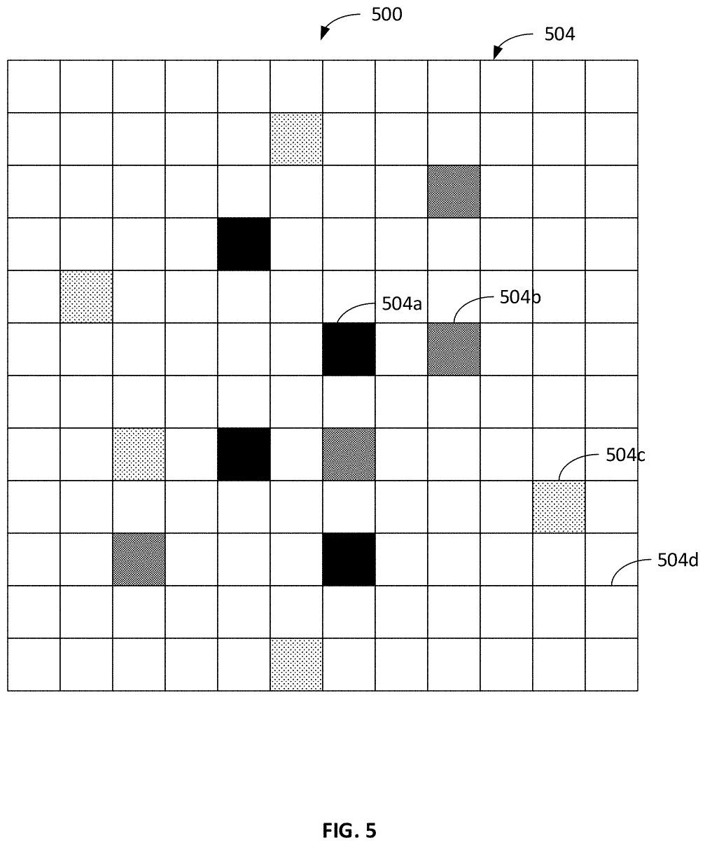

The metrics and/or categories for each grid block can be displayed to a user, such that the user can intuitively determine the portion of data that contributes to a convergence failure. As an example, FIG. 5 shows a graphical user interface (GUI) 500 for displaying metrics and/or severity levels to a user. The GUI 500 can be presented, for example, by any of the computer systems 104a-104d.

The graphical user interface 500 includes a visible presentation of a grid 502 having a number of grid blocks 504. Each of the grid blocks 504 can correspond to a different respective location in a reservoir 102. Further, the graphical user interface 500 indicates the severity level for each of the grid blocks 504. For example, a grid block 504a having a high severity level can be indicated using a first color or pattern, a grid block 504b having a medium severity level can be indicated using a second color or pattern, a grid block 504c having a low severity level can be indicated using a third color or pattern, and a grid block 504d having a very low severity level can be indicated using a fourth color or pattern.

### Example Processes

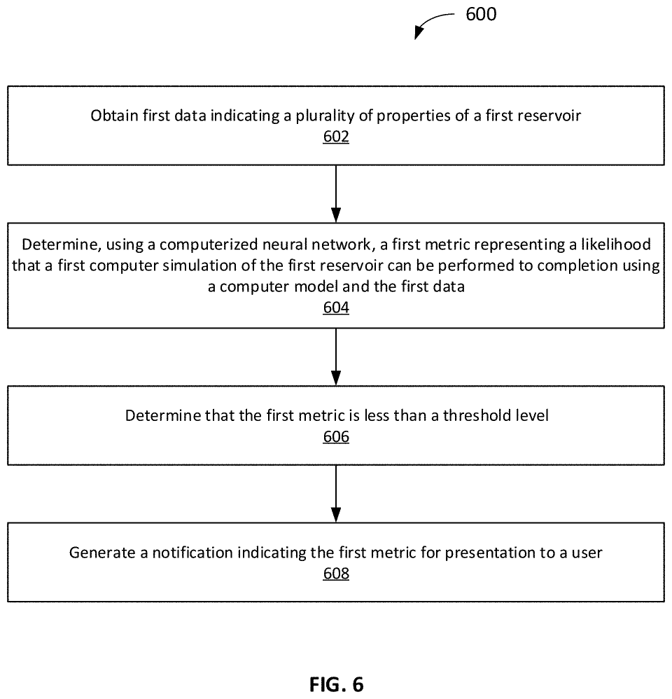

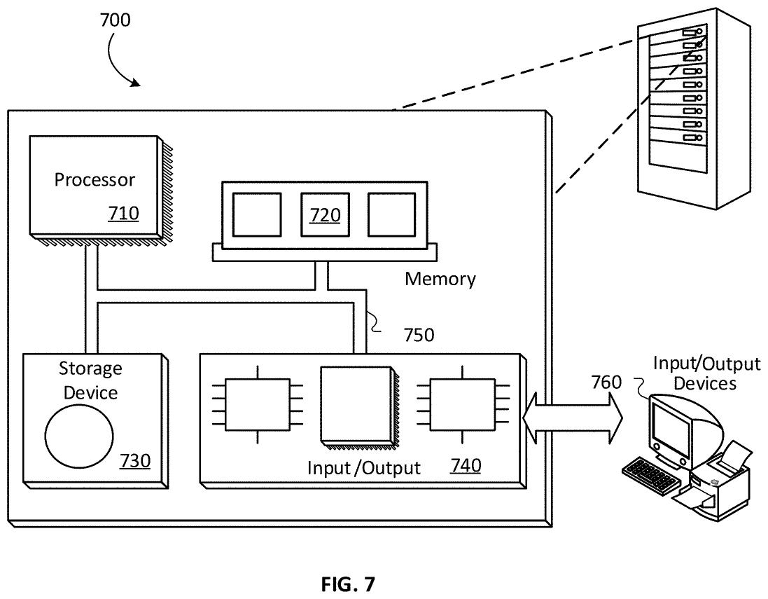

FIG. 6 shows an example process 600 for predicting and avoiding failures in computer simulations using machine learning. In some implementations, the process 600 can be performed by the system 100 described in this disclosure (for example, the system 100 including the failure prediction system 150 shown and described with respect to FIGS. 1, and 2) using one or more processors (for example, using the processor or processors 710 shown in FIG. 7).

In the process 600, one or more processors obtain first data indicating a plurality of properties of a first reservoir (block 602). In some implementations, the first data can include the industrial process data 112, the sensor data 114, and/or the input data 208b described with respect to FIGS. 1 and 2.

In some implementations, the properties of the first reservoir can include a characteristic of rock at a particular location of the reservoir, a physical geometry of the reservoir at the particular location, a permeability of the reservoir at the particular location, and/or a characteristics of fluid at the particular location of the reservoir. For example, the first data can include the sensor data 114 described with respect to FIG. 1.

In some implementations, the first data can indicate one or more characteristics of an industrial process performed at the reservoir. The industrial process can include a well production process and/or a fluid injection process. For example, the first data can include the industrial process data 112 described with respect to FIG. 1.

In some implementations, the first data can include one or more tolerances of the computer simulation. As an example, the input data can include one or more tolerances for a numerical solver used to perform the computer simulation.

The one or more processors implement a computerized neural network. The one or more processors determine, using the computerized neural network, a first metric representing a likelihood that a first computer simulation of the first reservoir can be performed to completion using a computer model and the first data (block 604).

In some implementations, the first computer simulation can simulate a time dependent flow of fluid through the reservoir.

In some implementations, the first metric can be determined prior to a performance of the first computer simulation of the first reservoir by a computer system. In some implementations, the computer system can be a distributed computer system.

In some implementations, the first metric can be determined by determining a spatial grid for performing the computer simulation of the reservoir. The spatial grid can include a plurality of grid blocks. Each of the grid blocks can correspond to a different respective spatial region of the reservoir. Further, for each of the grid blocks, a second metric can be determined for that grid block. Each of the second metrics can represent a likelihood that the properties of the first reservoir at a corresponding one of the spatial regions would cause the first computer simulation to terminate prior to completion due to one or more failure conditions.

In some implementations, the one or more failure conditions can include a convergence failure in performing an iterative process of the first computer simulation.

The one or more processors determine that the first metric is less than a threshold level (block 606).

In response to determining that the first metric is less than the threshold level, the one or more processors generate a notification indicating the first metric for presentation to a user (block 608).

In some implementations, in response to determining that the first metric is less than the threshold level, the one or more processors can also prevent the computer system from performing the first computer simulation using the computer model and the first data.

In some implementations, the one or more processors can also identify one or more portions of the first data that are likely to prevent the first computer simulation of the first reservoir from being performed to completion using the computer model. The notification can indicate the one or more identified portions of the first data.

In some implementations, the one or more processors can determine one or more modifications to the one or more portions of the first data that would enable the first computer simulation of the first reservoir to be performed to completion using the computer model. The notification indicates the one or more modifications. As an example, the modifications can include providing missing portions of the first data, removing outlier data and/or noise from the first data, and/or removing inconsistent portion of the first data. In some implementations, the one or more processors can modify the first data according to the one or more determined modifications.

In some implementations, the computerized neural network can be trained based a plurality of sets of training data regarding a plurality of additional reservoirs. Each of the sets of training data can include an indication of a plurality of properties of a respective one of the additional reservoirs, and an indication whether an additional computer simulation of that additional reservoirs was previously performed to completion using the computer model. In some implementations, the training data can include the training data 110 and/or the training data 208a, as described with respect to FIGS. 1 and 2.

### Example Systems

Some implementations of the subject matter and operations described in this specification can be implemented in digital electronic circuitry, or in computer software, firmware, or hardware, including the structures disclosed in this specification and their structural equivalents, or in combinations of one or more of them. For example, in some implementations, one or more components of the system 100 and the failure prediction system 150 can be implemented using digital electronic circuitry, or in computer software, firmware, or hardware, or in combinations of one or more of them. In another example, the processes 400 and 600 shown in FIGS. 4 and 6 can be implemented using digital electronic circuitry, or in computer software, firmware, or hardware, or in combinations of one or more of them.

Some implementations described in this specification can be implemented as one or more groups or modules of digital electronic circuitry, computer software, firmware, or hardware, or in combinations of one or more of them. Although different modules can be used, each module need not be distinct, and multiple modules can be implemented on the same digital electronic circuitry, computer software, firmware, or hardware, or combination thereof.

Some implementations described in this specification can be implemented as one or more computer programs, that is, one or more modules of computer program instructions, encoded on computer storage medium for execution by, or to control the operation of, data processing apparatus. A computer storage medium can be, or can be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate physical components or media (for example, multiple CDs, disks, or other storage devices).

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example, an FPGA (field programmable gate array) or an ASIC (application specific integrated circuit). The apparatus can also include, in addition to hardware, code that creates an execution environment for the computer program in question, for example, code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages. A computer program may, but need not, correspond to a file in a file system. A program can be stored in a portion of a file that holds other programs or data (for example, one or more scripts stored in a markup language document), in a single file dedicated to the program in question, or in multiple coordinated files (for example, files that store one or more modules, sub programs, or portions of code). A computer program can be deployed to be executed on one computer or on multiple computers that are located at one site or distributed across multiple sites and interconnected by a communication network.

Some of the processes and logic flows described in this specification can be performed by one or more programmable processors executing one or more computer programs to perform actions by operating on input data and generating output. The processes and logic flows can also be performed by, and apparatus can also be implemented as, special purpose logic circuitry, for example, an FPGA (field programmable gate array) or an ASIC (application specific integrated circuit).

Processors suitable for the execution of a computer program include, by way of example, both general and special purpose microprocessors, and processors of any kind of digital computer. Generally, a processor will receive instructions and data from a read only memory or a random access memory or both. A computer includes a processor for performing actions in accordance with instructions and one or more memory devices for storing instructions and data. A computer can also include, or be operatively coupled to receive data from or transfer data to, or both, one or more mass storage devices for storing data, for example, magnetic, magneto optical disks, or optical disks. However, a computer need not have such devices. Devices suitable for storing computer program instructions and data include all forms of non-volatile memory, media and memory devices, including by way of example semiconductor memory devices (for example, EPROM, EEPROM, AND flash memory devices), magnetic disks (for example, internal hard disks, and removable disks), magneto optical disks, and CD-ROM and DVD-ROM disks. The processor and the memory can be supplemented by, or incorporated in, special purpose logic circuitry.

To provide for interaction with a user, operations can be implemented on a computer having a display device (for example, a monitor, or another type of display device) for displaying information to the user. The computer can also include a keyboard and a pointing device (for example, a mouse, a trackball, a tablet, a touch sensitive screen, or another type of pointing device) by which the user can provide input to the computer. Other kinds of devices can be used to provide for interaction with a user as well. For example, feedback provided to the user can be any form of sensory feedback, such as visual feedback, auditory feedback, or tactile feedback. Input from the user can be received in any form, including acoustic, speech, or tactile input. In addition, a computer can interact with a user by sending documents to and receiving documents from a device that is used by the user. For example, a computer can send webpages to a web browser on a user's client device in response to requests received from the web browser.

A computer system can include a single computing device, or multiple computers that operate in proximity or generally remote from each other and typically interact through a communication network. Examples of communication networks include a local area network (“LAN”) and a wide area network (“WAN”), an inter-network (for example, the Internet), a network including a satellite link, and peer-to-peer networks (for example, ad hoc peer-to-peer networks). A relationship of client and server can arise by virtue of computer programs running on the respective computers and having a client-server relationship to each other.

FIG. 7 shows an example computer system 700 that includes a processor 710, a memory 720, a storage device 730 and an input/output device 740. Each of the components 710, 720, 730 and 740 can be interconnected, for example, by a system bus 750. The processor 710 is capable of processing instructions for execution within the system 700. In some implementations, the processor 710 is a single-threaded processor, a multi-threaded processor, or another type of processor. The processor 710 is capable of processing instructions stored in the memory 720 or on the storage device 730. The memory 720 and the storage device 730 can store information within the system 700.

The input/output device 740 provides input/output operations for the system 700. In some implementations, the input/output device 740 can include one or more of a network interface device, for example, an Ethernet card, a serial communication device, for example, an RS-232 port, or a wireless interface device, for example, an 802.11 card, a 3G wireless modem, a 4G wireless modem, or a 5G wireless modem, or both. In some implementations, the input/output device can include driver devices configured to receive input data and send output data to other input/output devices, for example, keyboard, printer and display devices 760. In some implementations, mobile computing devices, mobile communication devices, and other devices can be used.

While this specification contains many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable sub-combination.

A number of embodiments have been described. Nevertheless, various modifications can be made without departing from the spirit and scope of the invention. Accordingly, other embodiments are within the scope of the claims.

What is claimed is:

1. A method comprising:
obtaining, using one or more processors, first data indicating a plurality of properties of a first reservoir;
determining, using the one or more processors implementing a computerized neural network, a first metric representing a likelihood that a first computer simulation of the first reservoir can be performed to completion using a computer model and the first data;
determining, using the one or more processors, that the first metric is less than a threshold level; and
responsive to determining that the first metric is less than the threshold level, generating, using the one or more processors, a notification indicating the first metric for presentation to a user.

2. The method of claim 1, wherein the first metric is determined prior to a performance of the first computer simulation of the first reservoir by a computer system.

3. The method of claim 2, wherein the computer system is a distributed computer system.

4. The method of claim 1, further comprising:
responsive to determining that the first metric is less than the threshold level, preventing the computer system from performing the first computer simulation using the computer model and the first data.

5. The method of claim 1, further comprising:
identifying one or more portions of the first data that are likely to prevent the first computer simulation of the first reservoir from being performed to completion using the computer model,
wherein the notification indicates the one or more identified portions of the first data.

6. The method of claim 5, further comprising:
determining one or more modifications to the one or more portions of the first data that would enable the first computer simulation of the first reservoir to be performed to completion using the computer model,
wherein the notification indicates the one or more modifications.

7. The method of claim 6, further comprising:
modifying the first data according to the one or more determined modifications.

8. The method of claim 1, wherein the computerized neural network is trained based a plurality of sets of training data regarding a plurality of additional reservoirs, where each of the sets of training data comprises:
an indication of a plurality of properties of a respective one of the additional reservoirs, and
an indication whether an additional computer simulation of that additional reservoirs was previously performed to completion using the computer model .

9. The method of claim 1, wherein the properties of the first reservoir comprise at least one of:
a characteristic of rock at a particular location of the reservoir,
a physical geometry of the reservoir at the particular location,
a permeability of the reservoir at the particular location, or
a characteristics of fluid at the particular location of the reservoir.

10. The method of claim 1, wherein the first data further indicates one or more characteristics of an industrial process performed at the reservoir.

11. The method of claim 10, wherein the industrial process is at least one of a well production process or a fluid injection process.

12. The method of claim 1, wherein the first data further indicates one or more tolerances of the computer simulation.

13. The method of claim 1, wherein the first computer simulation simulates a time dependent flow of fluid through the reservoir.

14. The method of claim 1, wherein the determining the first metric comprises:
determining a spatial grid for performing the computer simulation of the reservoir, wherein the spatial grid comprises a plurality of grid blocks, and wherein each of the grid blocks corresponds to a different respective spatial region of the reservoir; and
determining, for each of the grid blocks, a second metric for that grid block, wherein each of the second metrics represents a likelihood that the properties of the first reservoir at a corresponding one of the spatial regions would cause the first computer simulation to terminate prior to completion due to one or more failure conditions.

15. The method claim 14, wherein the one or more failure conditions comprises a convergence failure in performing an iterative process of the first computer simulation.

16. A system comprising:
one or more processors; and
one or more non-transitory computer readable media storing instructions that, when executed by the one or more processors, cause the one or more processors to perform operations comprising:
obtaining first data indicating a plurality of properties of a first reservoir;
determining, using a computerized neural network, a first metric representing a likelihood that a first computer simulation of the first reservoir can be performed to completion using a computer model and the first data;
determining that the first metric is less than a threshold level; and
responsive to determining that the first metric is less than the threshold level, generating a notification indicating the first metric for presentation to a user.

17. One or more non-transitory computer readable media storing instructions that, when executed by one or more processors, cause the one or more processors to perform operations comprising:
obtaining first data indicating a plurality of properties of a first reservoir;
determining, using a computerized neural network, a first metric representing a likelihood that a first computer simulation of the first reservoir can be performed to completion using a computer model and the first data;
determining that the first metric is less than a threshold level; and
responsive to determining that the first metric is less than the threshold level, generating a notification indicating the first metric for presentation to a user.
